(19) United States
(12) Patent Application Publication
(10) Pub. No.: US 2020/0033739 A1
(43) Pub. Date: Jan. 30, 2020

(54) EXTREME ULTRAVIOLET LIGHT GENERATION DEVICE

(71) Applicant: Gigaphoton Inc., Tochigi (JP)

(72) Inventors: Tsukasa HORI, Oyama-shi (JP); Hirokazu HOSODA, Oyama-shi (JP)

(73) Assignee: Gigaphoton Inc., Tochigi (JP)

(21) Appl. No.: 16/593,274

(22) Filed: Oct. 4, 2019

Related U.S. Application Data
(63) Continuation of application No. PCT/JP2017/017159, filed on May 1, 2017.

(51) Int. Cl. G03F 7/20; H05G 2/00; G21K 1/06

(52) U.S. Cl. CPC G03F 7/70858; G03F 7/70033; G21K 1/06; H05G 2/008; H05G 2/005; G03F 7/70916

(57) ABSTRACT

An extreme ultraviolet light generation device according to an aspect of the present disclosure includes: a chamber in which tin is irradiated with a laser beam to generate extreme ultraviolet light; a hydrogen gas supply path that connects the chamber and a hydrogen-gas output unit of a hydrogen gas supply device as a supply source of hydrogen gas to be supplied into the chamber, receives supply of the hydrogen gas from the hydrogen gas supply device, and supplies, to the chamber, the hydrogen gas supplied from the hydrogen gas supply device; a temperature adjustment unit connected with the hydrogen gas supply path and configured to adjust the temperature of the hydrogen gas to be equal to or lower than 16° C.; and a gas discharge unit connected with the chamber and configured to discharge gas including at least hydrogen gas inside the chamber to outside of the chamber.

### CROSS-REFERENCE TO RELATED APPLICATIONS

The present application is a continuation application of International Application No. PCT/JP2017/017159 filed on May 1, 2017. The content of the application is incorporated herein by reference in its entirety.

### BACKGROUND

### 1. Technical Field

The present disclosure relates to an extreme ultraviolet light generation device.

### 2. Related Art

Recently, miniaturization of a transfer pattern in optical lithography of a semiconductor process has been rapidly proceeding along with miniaturization of the semiconductor process. Minute fabrication at 20 nm or smaller will be requested in the next generation technology. Thus, it is desired to develop an exposure apparatus including an extreme ultraviolet light generation device configured to generate extreme ultraviolet (EUV) light at a wavelength of 13 nm approximately in combination with reduced projection reflective optics.

EUV light generation devices include three kinds of devices of a laser produced plasma (LPP) device that uses plasma generated by irradiating a target material with a pulse laser beam, a discharge produced plasma (DPP) device that uses plasma generated by electrical discharge, and a synchrotron radiation (SR) device that uses orbital radiation light.

### LIST OF DOCUMENTS

### Patent Documents

Patent Document 1: National Publication of International Patent Application No. 2013-506280
Patent Document 2: Japanese Unexamined Patent Application Publication No. 8-75097

### SUMMARY

An extreme ultraviolet light generation device according to an aspect of the present disclosure includes: a chamber in which tin is irradiated with a laser beam to generate extreme ultraviolet light; a hydrogen gas supply path that connects the chamber and a hydrogen-gas output unit of a hydrogen gas supply device as a supply source of hydrogen gas to be supplied into the chamber, receives supply of the hydrogen gas from the hydrogen gas supply device, and supplies, to the chamber, the hydrogen gas supplied from the hydrogen gas supply device; a temperature adjustment unit connected with the hydrogen gas supply path and configured to adjust the temperature of the hydrogen gas to be equal to or lower than 16° C.; and a gas discharge unit connected with the chamber and configured to discharge gas including at least hydrogen gas inside the chamber to outside of the chamber.

### BRIEF DESCRIPTION OF THE DRAWINGS

Embodiments of the present disclosure will be described below as examples with reference to the accompanying drawings.

FIG. 1 is a diagram schematically illustrating the configuration of an exemplary LPP EUV light generation system.

FIG. 2 is a diagram schematically illustrating the configuration of an EUV light generation apparatus according to a first embodiment.

FIG. 3 is a diagram schematically illustrating the configuration of an EUV light generation apparatus according to a second embodiment.

FIG. 4 is a diagram schematically illustrating the configuration of an EUV light generation apparatus according to a third embodiment.

FIG. 5 is a partially enlarged view of an EUV light generation apparatus according to a fourth embodiment.

FIG. 6 is a partially enlarged view of an EUV light generation apparatus according to a fifth embodiment.

FIG. 7 is a cross-sectional view illustrating the configuration of an EUV optical sensor unit of an EUV light generation apparatus according to a sixth embodiment.

FIG. 8 is a cross-sectional view illustrating the configuration of a droplet detection device of an EUV light generation apparatus according to a seventh embodiment.

FIG. 9 is a diagram schematically illustrating the configuration of a heat exchanger.

### DESCRIPTION OF EMBODIMENTS

### <Contents>

1. Overall description of extreme ultraviolet light generation system

1.1 Configuration

1.2 Operation

### 2. Terms

### 3. Problem

### 4. First Embodiment

4.1 Configuration

4.2 Operation

4.3 Effect

### 5. Second Embodiment

5.1 Configuration

5.2 Operation

5.3 Effect

### 6. Third Embodiment

6.1 Configuration

6.2 Operation

6.3 Effect

### 7. Fourth Embodiment

7.1 Configuration

7.2 Operation

7.3 Effect

### 8. Fifth Embodiment

8.1 Configuration

8.2 Operation

8.3 Effect

### 9. Sixth Embodiment

9.1 Configuration

9.2 Operation

9.3 Effect

### 10. Seventh Embodiment

10.1 Configuration

10.2 Operation

10.3 Effect

11. Heat exchanger

11.1 Configuration

11.2 Operation

Embodiments of the present disclosure will be described below in detail with reference to the accompanying drawings.

The embodiments described below are examples of the present disclosure, and do not limit the contents of the present disclosure. Not all configurations and operations described in each embodiment are necessarily essential as configurations and operations of the present disclosure. Components identical to each other are denoted by an identical reference sign, and duplicate description thereof will be omitted.

### 1. Overall Description of Extreme Ultraviolet Light Generation System

1.1 Configuration

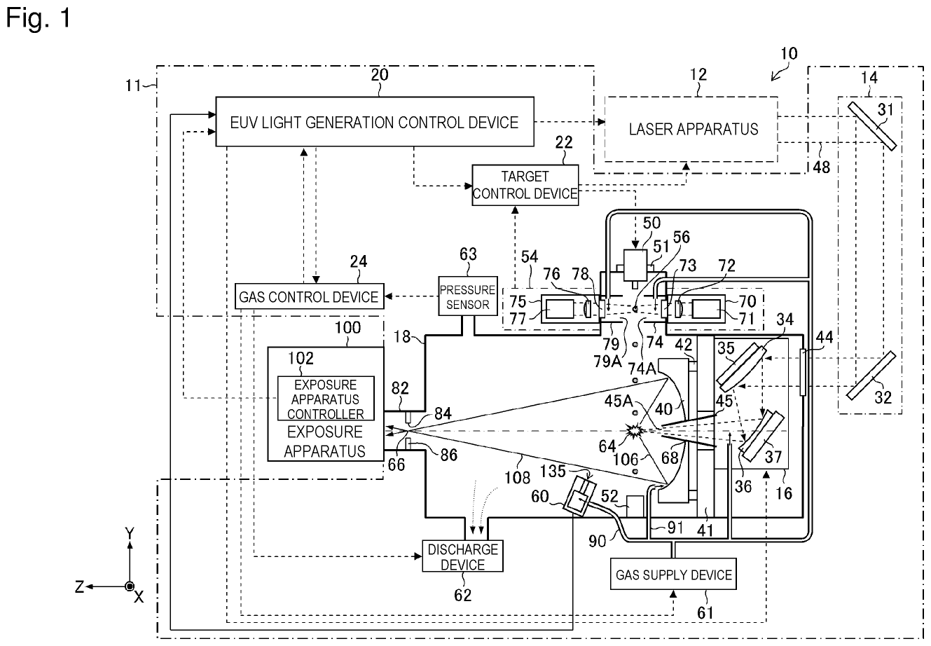

FIG. 1 schematically illustrates the configuration of an exemplary LPP EUV light generation system 10. An EUV light generation apparatus 11 is used together with at least one laser apparatus 12 in some cases. In the present disclosure, the EUV light generation system 10 is a system including the EUV light generation apparatus 11 and the laser apparatus 12.

As illustrated in FIG. 1 and described below in detail, the EUV light generation apparatus 11 includes a laser beam transmission device 14, a chamber 18, an EUV light generation control device 20, a target control device 22, and a gas control device 24.

The laser apparatus 12 may be a master oscillator power amplifier (MOPA) system. The laser apparatus 12 may include a master oscillator (not illustrated), an optical isolator (not illustrated), and a plurality of CO₂ laser amplifiers (not illustrated). The master oscillator can output, at a predetermined repetition frequency, a laser beam having a wavelength in the amplification region of each CO₂ laser amplifier. The wavelength of the laser beam output from the master oscillator is, for example, 10.59 μm, and the predetermined repetition frequency thereof is, for example, 100 kHz. The master oscillator may be a solid-state laser.

The laser beam transmission device 14 includes an optical component for defining the traveling direction of a laser beam, and an actuator for adjusting the position, posture, and the like of the optical component. The laser beam transmission device 14 illustrated in FIG. 1 includes a first high reflection mirror 31 and a second high reflection mirror 32 as optical components for defining the traveling direction of a laser beam.

The chamber 18 is a sealable container. The chamber 18 may be formed in, for example, a hollow spherical or tubular shape. The chamber 18 includes a laser beam condensation unit 16. The laser beam condensation unit 16 includes a first laser reflection mirror 34 and a second laser reflection mirror 36.

The first laser reflection mirror 34 is held by a holder 35. The holder 35 is fixed to a triaxial stage (not illustrated). The triaxial stage can move the holder 35 in directions along the three axes of an X axis, a Y axis, and a Z axis orthogonal to each other.

The second laser reflection mirror 36 is held by a holder 37. The holder 37 is fixed to a triaxial stage (not illustrated). The triaxial stage can move the holder 37 in directions along the three axes of an X axis, a Y axis, and a Z axis orthogonal to each other.

In FIG. 1, a Z axis is defined to be a direction in which EUV light is guided from the chamber 18 toward an exposure apparatus 100. An X axis is defined to be a direction orthogonal to the sheet of FIG. 1, and a Y axis is defined to be a longitudinal direction parallel to the sheet. The laser beam condensation unit 16 condenses a laser beam transmitted by the laser beam transmission device 14 onto a plasma generating region 64 in the chamber 18.

The chamber 18 includes an EUV light focusing mirror 40, a plate 41, an EUV light focusing mirror holder 42, a first window 44, and a first cover 45. The chamber 18 also includes a target supply unit 50, a biaxial stage 51, a droplet receiver 52, a droplet detection device 54, an EUV optical sensor unit 60, a gas supply device 61, a discharge device 62, and a pressure sensor 63.

The wall of the chamber 18 is provided with at least one through-hole. The through-hole is blocked by the first window 44. A pulse laser beam 48 output from the laser apparatus 12 transmits through the first window 44 via the laser beam transmission device 14.

The EUV light focusing mirror 40 has, for example, a spheroidal surface and first and second focuses. For example, a multi-layer reflective film obtained by alternately stacking molybdenum and silicon is formed on the surface of the EUV light focusing mirror 40. For example, the EUV light focusing mirror 40 is disposed so that the first focus is positioned in the plasma generating region 64 and the second focus is positioned at an intermediate focusing point (IF) 66. The EUV light focusing mirror 40 is provided with a through-hole 68 at a central part thereof through which a pulse laser beam 48 passes.

The plate 41 and the EUV light focusing mirror holder 42 are members holding the EUV light focusing mirror 40. The plate 41 is fixed to the chamber 18. The EUV light focusing mirror 40 is held by the plate 41 through the EUV light focusing mirror holder 42.

The first cover 45 is a shroud covering an optical path through which the pulse laser beam 48 is guided from the first window 44 to the plasma generating region 64 through the through-hole 68. The first cover 45 has a tubular substantially circular truncated cone shape tapering from the first window 44 toward the plasma generating region 64.

The target supply unit 50 supplies a target substance into the chamber 18 and is, for example, attached to penetrate through the wall of the chamber 18. The target supply unit 50 is attached to the wall of the chamber 18 through the biaxial stage 51. The biaxial stage 51 is an XZ-axis stage that can move the target supply unit 50 in the directions of the X and Z axes. The position of the target supply unit 50 on the XZ plane can be adjusted through the biaxial stage 51.

The target substance is made of tin. The target supply unit 50 outputs a droplet 56 formed from the target substance toward the plasma generating region 64 in the chamber 18.

The target control device 22 is electrically connected with each of the EUV light generation control device 20, the laser apparatus 12, the target supply unit 50, and the droplet detection device 54. The target control device 22 controls operation of the target supply unit 50 in accordance with a command from the EUV light generation control device 20. The target control device 22 also controls the output timing of the pulse laser beam 48 from the laser apparatus 12 based on a detection signal from the droplet detection device 54.

The droplet detection device 54 detects one or a plurality of the existence, locus, position, and speed of the droplet 56. The droplet detection device 54 is disposed to detect trajectory change in the X direction. The droplet detection device 54 includes a light source unit 70 and a light receiving unit 75.

The light source unit 70 includes a light source 71, an illumination optical system 72, a second window 73, and a second cover 74. The light source 71 may be a lamp, a semiconductor laser, or the like. The illumination optical system 72 may be a condenser lens through which the droplet trajectory is illuminated with light output from the light source 71.

The light receiving unit 75 includes a transfer optical system 76, a first optical sensor 77, a third window 78, and a third cover 79. The transfer optical system 76 may be a lens through which an image of the droplet 56 being illuminated is transferred onto an element of the first optical sensor 77. The first optical sensor 77 may be a two-dimensional image sensor such as a charge-coupled device (CCD).

The chamber 18 includes another droplet detection device (not illustrated) configured to detect shift in the trajectory of the droplet 56 in the Z direction.

The droplet receiver 52 is disposed on an extended line in the direction in which the droplet 56 output from the target supply unit 50 into the chamber 18 travels. In FIG. 1, the droplet 56 drops in a direction parallel to the Y axis, and the droplet receiver 52 is disposed at a position opposite to the target supply unit 50 in the Y direction.

The EUV light generation apparatus 11 includes a connection unit 82 through which the inside of the chamber 18 and the inside of the exposure apparatus 100 are communicated with each other. A wall 86 on which an aperture 84 is formed is provided inside the connection unit 82. The wall 86 is disposed so that the aperture 84 is positioned at the second focus of the EUV light focusing mirror 40.

The exposure apparatus 100 includes an exposure apparatus controller 102 electrically connected with the EUV light generation control device 20.

The EUV optical sensor unit 60 detects EUV light generated in the chamber 18. The EUV optical sensor unit 60 is electrically connected with the EUV light generation control device 20. A plurality of EUV optical sensor units 60 may be provided to observe plasma from a plurality of positions different from each other. FIG. 1 illustrates one EUV optical sensor unit 60, but EUV optical sensor units 60 are preferably disposed at a plurality of places around the chamber 18.

The gas supply device 61 is connected with a space inside each of the first cover 45, the second cover 74, the third cover 79, and the EUV optical sensor unit 60 through a pipe 90. The gas supply device 61 is also connected with a pipe 91 through which gas flows to the surface of the EUV light focusing mirror 40. The gas supply device 61 is a gas supply source that supplies gas to the pipe 90 and the pipe 91.

The gas control device 24 is electrically connected with each of the EUV light generation control device 20, the gas supply device 61, the discharge device 62, and the further pressure sensor 63. The discharge device 62 discharges gas in the chamber 18 to the outside of the chamber 18 in accordance with a command from the gas control device 24. The pressure sensor 63 detects the pressure in the chamber 18. A detection signal from the pressure sensor 63 is transferred to the gas control device 24. The gas control device 24 controls operation of the gas supply device 61 and the discharge device 62 in accordance with a command from the EUV light generation control device 20.

The EUV light generation control device 20 collectively controls the entire EUV light generation system 10. The EUV light generation control device 20 processes a result of detection by the EUV optical sensor unit 60. The EUV light generation control device 20 may control, for example, the timing at which the droplet 56 is output, the direction in which the droplet 56 is output, and the like based on a result of detection by the droplet detection device 54. In addition, the EUV light generation control device 20 may control, for example, the oscillation timing of the laser apparatus 12, the traveling direction of the pulse laser beam 48, the focusing position of the pulse laser beam 48, and the like. These various kinds of control are merely exemplary, and may include other control as necessary or may omit part of the control function.

In the present disclosure, control devices such as the EUV light generation control device 20, the target control device 22, the gas control device 24, and the exposure apparatus controller 102 can be actualized by hardware and software combination of one or a plurality of computers. The software is synonymous with a computer program. Functions of a plurality of control devices may be achieved by a single control device. In the present disclosure, the EUV light generation control device 20, the target control device 22, the gas control device 24, the exposure apparatus controller 102, and the like may be electrically connected with each other through a communication network such as a local area network or the Internet. In a distributed computing environment, a computer program unit may be stored in local and remote memory storage devices.

1.2 Operation

The following describes operation of the exemplary LPP EUV light generation system 10 with reference to FIG. 1. When EUV light is to be output from the EUV light generation system 10, an EUV light output command is transferred from the exposure apparatus controller 102 of the exposure apparatus 100 to the EUV light generation control device 20.

The EUV light generation control device 20 transmits a control signal to the gas control device 24. The gas control device 24 controls the gas supply device 61 and the discharge device 62 so that the chamber 18 has pressure in a predetermined range based on a value detected by the pressure sensor 63.

The predetermined range of the pressure in the chamber 18 is, for example, between several Pa to several hundred Pa. Hydrogen gas fed out from the gas supply device 61 is supplied into each of the first cover 45, the second cover 74, and the third cover 79, and into the EUV optical sensor unit 60 through the pipe 90. The hydrogen gas fed out from the gas supply device 61 is also supplied to the reflection surface of the EUV light focusing mirror 40 through the pipe 91.

The hydrogen gas supplied into the first cover 45 is ejected through an opening 45A of the first cover 45. The hydrogen gas supplied into the second cover 74 is ejected through an opening 74A of the second cover 74. The hydrogen gas supplied into the third cover 79 is ejected through an opening 79A of the third cover 79. The hydrogen gas supplied into the EUV optical sensor unit 60 is ejected through an opening 135 of the EUV optical sensor unit 60.

When the internal pressure of the chamber 18 has become a pressure in the predetermined range, the gas control device 24 transmits a signal to the EUV light generation control device 20. Having received the signal transmitted from the gas control device 24, the EUV light generation control device 20 transmits a droplet output instruction signal that instructs the target control device 22 to output a droplet.

Having received the droplet output instruction signal, the target control device 22 transmits a droplet output signal to the target supply unit 50 to output the droplet 56. The droplet 56 is a droplet of melted tin (Sn).

The trajectory of the droplet 56 output from the target supply unit 50 is detected by the droplet detection device 54. A detection signal of the detection by the droplet detection device 54 is transferred to the target control device 22.

The target control device 22 may transmit a feedback signal to the biaxial stage 51 so that the trajectory of the droplet 56 coincides with a desired trajectory based on the detection signal obtained from the droplet detection device 54.

When the trajectory of the droplet 56 has become stable, the target control device 22 outputs, to the laser apparatus 12, a trigger signal delayed by a predetermined time in synchronization with an output signal of the droplet 56. This delay time is set so that the droplet 56 is irradiated with a laser beam when the droplet 56 reaches the plasma generating region 64.

The laser apparatus 12 outputs a laser beam in synchronization with the trigger signal. The power of the laser beam output from the laser apparatus 12 is several kW to several tens kW. The laser beam output from the laser apparatus 12 is incident on the first laser reflection mirror 34 of the laser beam condensation unit 16 through the laser beam transmission device 14. The laser beam incident on the first laser reflection mirror 34 is reflected by the first laser reflection mirror 34 and incident on the second laser reflection mirror 36.

The laser beam incident on the second laser reflection mirror 36 is reflected by the second laser reflection mirror 36, passes through the first window 44, and is input to the chamber 18. The droplet 56 having reached the plasma generating region 64 is irradiated with the laser beam incident on the chamber 18 through the first laser reflection mirror 34 and the second laser reflection mirror 36.

The droplet 56 is irradiated with at least one pulse included in the pulse laser beam 48. Plasma is generated when the droplet 56 is irradiated with the pulse laser beam, and irradiates radiation light 106. EUV light 108 included in the radiation light 106 is selectively reflected by the EUV light focusing mirror 40. The EUV light 108 reflected by the EUV light focusing mirror 40 is condensed at the intermediate focus point 66 and output to the exposure apparatus 100. The single droplet 56 may be irradiated with a plurality of pulses included in the pulse laser beam 48.

The droplet receiver 52 collects the droplet 56 not irradiated with a laser beam but having passed through the plasma generating region 64, and a droplet part not diffused by laser beam irradiation.

The EUV optical sensor unit 60 observes EUV light included in the radiation light 106 radiated from plasma. The energy of the EUV light radiated from plasma may be measured based on a signal obtained from the EUV optical sensor unit 60 to measure the energy of EUV light generated in the chamber 18.

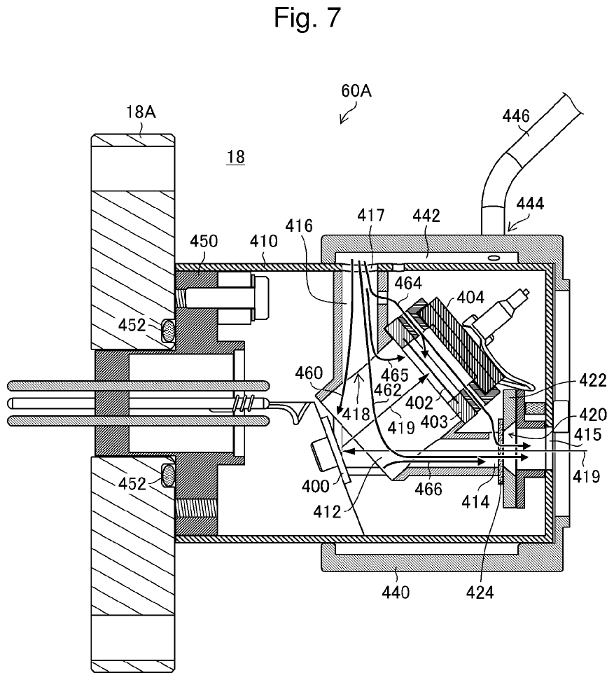

Part of the radiation light 106 enters the EUV optical sensor unit 60 through the opening 135. The EUV light having entered the EUV optical sensor unit 60 is received by an EUV sensor included in the EUV optical sensor unit 60. The energy of the EUV light can be detected based on a signal output from the EUV sensor. FIG. 1 omits illustration of the EUV sensor. The EUV sensor is denoted by reference sign 404 in FIG. 7.

When a plurality of EUV optical sensor units 60 are provided, the position of plasma can be calculated based on the position of detection by each EUV optical sensor unit and detected energy.

Along with plasma generation, Sn debris may be generated and diffused in the chamber 18. In this case, the Sn debris is Sn (tin) fine particles. The diffused Sn debris may reach the opening 45A of the first cover 45, the opening 74A of the second cover 74, the opening 79A of the third cover 79, and the opening 135 of the EUV optical sensor unit 60.

Hydrogen gas is ejected through each of the opening 45A of the first cover 45, the opening 74A of the second cover 74, the opening 79A of the third cover 79, and the opening 135 of the EUV optical sensor unit 60. This can prevent the Sn debris from reaching the first window 44, the second window 73, the third window 78, and an EUV light reflection mirror in the EUV optical sensor unit 60.

When the gas supplied to the surface of the EUV light focusing mirror 40 is hydrogen, stannane gas (SnH₄) is generated through reaction between the Sn debris accumulated on the EUV light focusing mirror 40 and the hydrogen. Gas including the stannane gas is discharged to the outside of the chamber 18 by the discharge device 62 without circulation or the like inside the chamber 18. The discharge device 62 is an exemplary gas discharge unit.

The gas discharged to the outside of the chamber 18 may include hydrogen gas. The hydrogen gas discharged to the outside of the chamber 18 is not reused but is discarded. For example, the hydrogen gas may be provided with determined processing and then discharged to atmosphere.

Similarly, gas including hydrogen is supplied around the first laser reflection mirror 34, the second laser reflection mirror 36, the first window 44, the second window 73, and the third window 78. This reduces Sn debris accumulation on the first laser reflection mirror 34, the second laser reflection mirror 36, the first window 44, the second window 73, and the third window 78.

### 2. Terms

“Target” is an object irradiated with a laser beam supplied to the chamber. When irradiated with the laser beam, the target generates plasma and radiates EUV light. A droplet formed from a liquid target substance is a form of the target.

“Plasma light” is radiation light radiated from the target as plasma. This radiation light includes EUV light.

“EUV light” stands for “extreme ultraviolet light”.

“Optical component” is synonymous with an optical element and an optical member.

“Room temperature” is an optional temperature in the temperature range of 20° C. to 25° C. inclusive.

### 3. Problem

Optical performance such as the reflectance or transmissivity of an optical component such as the EUV light focusing mirror 40 inside the chamber 18 degrades due to adhesion of tin to the optical component and accumulation of adhered tin.

It is known that, to solve this problem, the optical component is cooled to a temperature lower than room temperature so that tin is unlikely to accumulate on the optical component, which can lead to lifetime extension of the optical component. For example, cooling water is used to cool the optical component to approximately 5° C. to 16° C. that is lower than room temperature.

In addition, it is known that supplying hydrogen gas to the inside of the chamber 18, in particular, the surface of the optical component is effective for reducing tin adhesion to the optical component. This is because degradation of the optical performance of the optical component due to tin adhesion is reduced by using the hydrogen gas as etching gas to etch tin adhering to the optical component and generate gas of stannane (SnH₄) through reaction between hydrogen gas and tin and efficiently eject the stannane gas.

However, because hydrogen has a larger heat capacity than other gas, when hydrogen gas at room temperature is supplied into the chamber 18, heat of the hydrogen gas is provided to an optical component inside the chamber 18, which can increase the temperature of the optical component.

In addition, because hydrogen has a higher thermal conductivity than other gas, when supplied into the chamber 18, hydrogen gas at room temperature promotes heat communication between an optical component inside the chamber 18 cooled to a temperature lower than room temperature and the wall of the chamber 18 at room temperature. As a result, the hydrogen gas at room temperature heats the optical component inside the chamber 18 cooled to a temperature lower than room temperature.

Furthermore, the hydrogen gas is supplied at room temperature to the chamber 18 and not provided with temperature management. Due to characteristics of the heat capacity and thermal conductivity of the hydrogen gas, hydrogen supplied at room temperature can disturb temperature management of the optical component inside the chamber 18.

The optical component inside the chamber 18 is cooled to a temperature lower than room temperature to prevent tin contamination of the optical component inside the chamber 18. Thus, the hydrogen gas at room temperature may heat the optical component inside the chamber 18. The temperature of the optical component inside the chamber 18 increases when the hydrogen gas at room temperature is supplied into the chamber 18. This promotes reaction through which stannane returns to tin, and may promote tin contamination of the optical component inside the chamber 18 or the like.

### 4. First Embodiment

4.1 Configuration

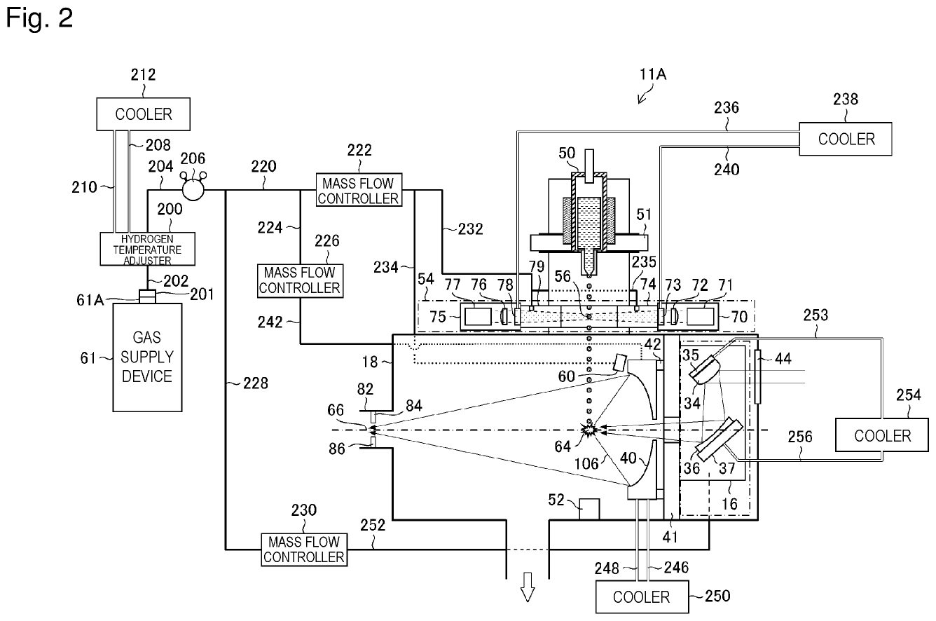

FIG. 2 is a diagram schematically illustrating the configuration of an EUV light generation apparatus according to a first embodiment. FIG. 2 omits illustration of the laser apparatus 12, the laser beam transmission device 14, the EUV light generation control device 20, the target control device 22, the gas control device 24, the discharge device 62, the pressure sensor 63, the exposure apparatus 100, and the exposure apparatus controller 102, which are illustrated in FIG. 1.

An EUV light generation apparatus 11A illustrated in FIG. 2 is different from the EUV light generation apparatus 11 illustrated in FIG. 1 in disposition of the EUV optical sensor unit 60. However, the EUV optical sensor unit 60 illustrated in FIG. 2 has functions identical to those of the EUV optical sensor unit 60 illustrated in FIG. 1. The EUV light generation apparatus 11A is an exemplary extreme ultraviolet light generation device.

The EUV light generation apparatus 11A illustrated in FIG. 2 includes a cooler 212, a cooler 238, a cooler 250, and a cooler 254 in addition to the configuration of the EUV light generation apparatus 11 illustrated in FIG. 1. The EUV light generation apparatus 11A illustrated in FIG. 2 also includes a first mass flow controller 222, a second mass flow controller 226, and a third mass flow controller 230 in addition to the configuration of the EUV light generation apparatus 11 illustrated in FIG. 1.

The EUV light generation apparatus 11A illustrated in FIG. 2 includes a hydrogen temperature adjuster 200. The hydrogen temperature adjuster 200 is connected with the gas supply device 61 through a gas pipe 202. In the EUV light generation apparatus 11A illustrated in FIG. 2, the gas supply device 61 is connected with the gas pipe 202 by coupling a hydrogen gas output unit 61A of the gas supply device 61 with a joint 201 provided at an end of the gas pipe 202.

The hydrogen gas output unit 61A of the gas supply device 61 coupled with the joint 201 of the gas pipe 202 may be an end of a pipe extended from the gas supply device 61 or may be an output unit of a component connected with the pipe extended from the gas supply device 61.

The gas supply device 61 includes a tank filled with high-pressure hydrogen in a sealed manner or a cylinder bundle of a plurality of such tanks coupled with each other. Each tank is initially filled at a pressure equal to 10 MPa or higher. In the present disclosure, for example, the tank is initially filled with high-pressure hydrogen at the pressure of 14.0 MPa. Hydrogen gas supplied from the tank or the cylinder bundle does not include hydrogen gas discharged by the discharge device 62.

The gas supply device 61 as the supply source of hydrogen gas is an exemplary hydrogen gas supply device. The gas supply device 61 including a tank or a cylinder bundle is an exemplary hydrogen gas supply device of a non-circulation type.

The hydrogen temperature adjuster 200 is connected with a regulator 206 through a gas pipe 204. Specifically, the hydrogen temperature adjuster 200 is disposed between the gas supply device 61 as the high-pressure hydrogen gas source and the regulator 206. In other words, the hydrogen temperature adjuster 200 is connected with a hydrogen gas supply path upstream of the regulator 206. The gas pipe 202 is an exemplary hydrogen gas supply path

The hydrogen temperature adjuster 200 is connected with the cooler 212 through a cooling water pipe 208 and a cooling water pipe 210. A cooling pipe provided inside the hydrogen temperature adjuster 200 is connected with the cooling water pipe 208 and the cooling water pipe 210. The combination of the hydrogen temperature adjuster 200 and the cooler 212 is an exemplary temperature adjustment unit.

The regulator 206 is connected with the first mass flow controller 222 through a gas pipe 220. The regulator 206 is connected with the second mass flow controller 226 through a gas pipe 224. The regulator 206 is connected with the third mass flow controller 230 through a gas pipe 228.

The first mass flow controller 222 is connected with the second cover 74 through a gas pipe 235. The first mass flow controller 222 is connected with the third cover 79 through a gas pipe 232. The first mass flow controller 222 is connected with the EUV optical sensor unit 60 through a gas pipe 234.

The second cover 74 is connected with the cooler 238 through a cooling water pipe 240. A cooling pipe provided inside the second cover 74 is connected with the cooling water pipe 240. The third cover 79 is connected with the cooler 238 through a cooling water pipe 236. A cooling pipe provided inside the third cover 79 is connected with the cooling water pipe 236. The cooling pipe provided inside the second cover 74 and the cooling pipe provided inside the third cover 79 are not illustrated.

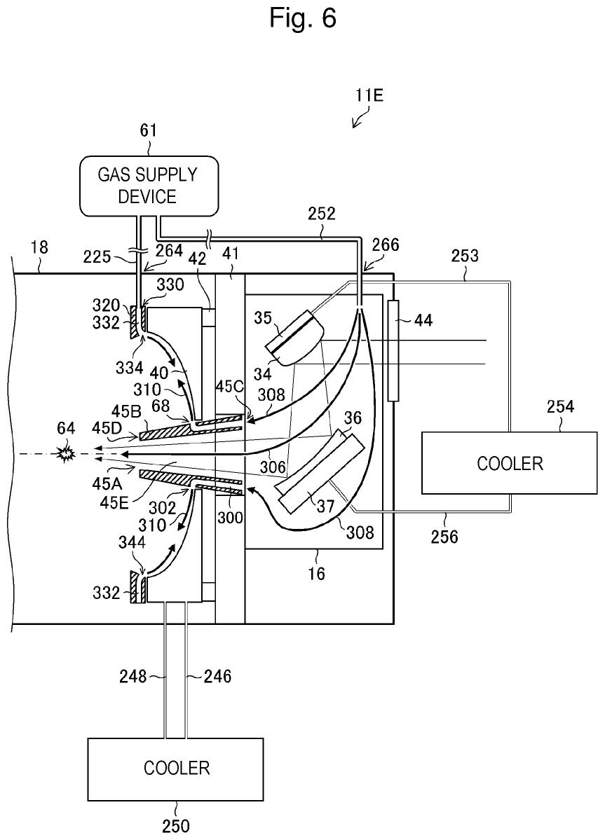

The second mass flow controller 226 is connected with a gas feed unit of the EUV light focusing mirror 40 through a gas pipe 242. The gas feed unit of the EUV light focusing mirror 40 supplies hydrogen gas to the reflection surface of the EUV light focusing mirror 40. The gas feed unit will be described later in detail. FIG. 2 omits illustration of the gas feed unit. The gas feed unit is denoted by reference sign 320 in FIG. 6.

A cooling pipe provided inside the EUV light focusing mirror 40 is connected with the cooler 250 through a cooling water pipe 246 and a cooling water pipe 248. The cooling pipe provided inside the EUV light focusing mirror 40 is not illustrated.

The third mass flow controller 230 is connected with the laser beam condensation unit 16 through a gas pipe 252. A cooling pipe provided inside the first laser reflection mirror 34 is connected with the cooler 254 through a cooling water pipe 253. Gas pipes downstream of the hydrogen temperature adjuster 200, such as the gas pipe 204 and the gas pipe 220 are exemplary components of the hydrogen gas supply path.

A cooling pipe provided inside the second laser reflection mirror 36 is connected with the cooler 254 through a cooling water pipe 256. The cooling pipe provided inside the first laser reflection mirror 34 and the cooling pipe provided inside the second laser reflection mirror 36 are not illustrated.

The gas control device 24 illustrated in FIG. 1 is electrically connected with the first mass flow controller 222, the second mass flow controller 226, and the third mass flow controller 230 illustrated in FIG. 2. The gas control device 24 illustrated in FIG. 1 is electrically connected with the cooler 212 illustrated in FIG. 2.

A temperature adjustment control device (not illustrated) is electrically connected with the cooler 238, the cooler 250, and the cooler 254. The cooling medium of each of the cooler 212, the cooler 238, the cooler 250, and the cooler 254 may be water or fluid other than water.

The cooler 238, the cooler 250, and the cooler 254 are exemplary components of an optical component cooling mechanism configured to cool an optical component.

Components on the chamber 18 side of the hydrogen temperature adjuster 200, which are downstream of the hydrogen temperature adjuster 200 on the circulation path of hydrogen gas, are provided with dew condensation prevention. Exemplary components provided with the dew condensation prevention include a gas pipe such as the gas pipe 204, a mass flow controller such as the first mass flow controller 222, and the regulator 206, which are illustrated in FIG. 2.

In exemplary dew condensation prevention, a heat insulation material is wrapped around a component to be provided with the dew condensation prevention, a pipe such as the gas pipe 204 is changed to a double pipe, and a component to be provided with the dew condensation prevention is stored in a housing into which dry gas is supplied. Exemplary heat insulation materials include glass wool, polyurethane, and foamed polystyrene.

4.2 Operation

The gas supply device 61 feeds out hydrogen gas. The hydrogen gas fed out from the gas supply device 61 is supplied to the hydrogen temperature adjuster 200. The hydrogen temperature adjuster 200 cools, by using the cooler 212, the temperature of the hydrogen gas supplied to the hydrogen temperature adjuster 200 to the cooling temperature of the optical component inside the chamber 18 or lower. The hydrogen temperature adjuster 200 can cool the hydrogen gas through adiabatic expansion by cooling the hydrogen gas at a high-pressure part upstream of the regulator 206.

The optical component inside the chamber 18 includes an optical component disposed inside the chamber 18. The optical component inside the chamber 18 includes an optical component, at least part of which is exposed inside the chamber 18.

The gas control device 24 illustrated in FIG. 1 controls the hydrogen gas temperature adjustment processing performed by the hydrogen temperature adjuster 200 illustrated in FIG. 2. The gas control device 24 illustrated in FIG. 1 sets the adjustment temperature of the cooler 212 in accordance with an adjustment temperature set to each of the cooler 238, the cooler 250, and the cooler 254 illustrated in FIG. 2. The adjustment temperatures of the cooler 238, the cooler 250, and the cooler 254 may be individually set in accordance with the adjustment temperature of an optical component, the temperature of which is to be adjusted.

The temperature adjustment control device (not illustrated) controls operation of the cooler 238, the cooler 250, and the cooler 254 in accordance with the adjustment temperature set to each of the cooler 238, the cooler 250, and the cooler 254 illustrated in FIG. 2.

The cooler 254 cools the first window 44, the first laser reflection mirror 34, and the second laser reflection mirror 36 disposed inside the chamber 18. The cooler 250 cools the EUV light focusing mirror 40 disposed inside the chamber 18. The cooler 238 cools the second window 73 and the third window 78.

The adjustment temperature of the cooler 250 is denoted by t₁, the adjustment temperature of the cooler 254 is denoted by t₂, the adjustment temperature of the cooler 238 is denoted by t₃, the adjustment temperature of the hydrogen temperature adjuster 200 as the adjustment temperature of the cooler 212 is denoted by tₕ, and room temperature is denoted by tᵣ. The adjustment temperatures of the coolers may have the relation of “tᵣ>t₃>tₕ>t₂>t₁”. Alternatively, the adjustment temperatures of the coolers may have the relation of “tᵣ>t₃>t₂>tₕ>t₁”. Alternatively, the adjustment temperatures of the coolers may have the relation of “tᵣ>t₃>t₂>t₁>tₕ”.

The adjustment temperature of the optical component disposed inside the chamber 18 may be lower than 20° C. Specifically, t₁ may be lower than 20° C., t₂ may be lower than 20° C., and t₃ may be lower than 20° C. The adjustment temperature of the optical component disposed inside the chamber 18 is preferably 5° C. to 16° C. inclusive. The adjustment temperature of the optical component disposed inside the chamber 18 is more preferably 5° C. to 12° C. inclusive. When the adjustment temperature of the optical component is equal to or lower than 16° C., the temperature of hydrogen gas supplied into the chamber 18 is cooled to 16° C. or lower. The temperature of 16° C. is a temperature below which dew condensation in a clean room can be avoided. When the adjustment temperature of the optical component is equal to or lower than 12° C., the temperature of hydrogen gas supplied into the chamber 18 is cooled to 12° C. or lower. In cooling of the optical component, the adjustment temperature means the cooling temperature thereof.

The optical components disposed inside the chamber 18 include the first laser reflection mirror 34, the second laser reflection mirror 36, the EUV light focusing mirror 40, the first window 44, the second window 73, and the third window 78.

The adjustment temperature of hydrogen gas adjusted by the hydrogen temperature adjuster 200 may be set to be equal to or lower than the adjustment temperature in cooling of each optical component disposed inside the chamber 18. The adjustment temperature in cooling of the optical component may be equal to or lower than the temperature of cooling water used by a cooling unit that cools the optical component. The temperature of the cooling water may be equal to or higher than 5° C. The temperature of the cooling water preferably exceeds 0° C. The temperature of the cooling water may be a temperature at an output port of each cooler.

The adjustment temperature of hydrogen gas adjusted by the hydrogen temperature adjuster 200 may be set to be equal to or lower than the lowest adjustment temperature among the adjustment temperature of the first laser reflection mirror 34, the adjustment temperature of the second laser reflection mirror 36, the adjustment temperature of the EUV light focusing mirror 40, the adjustment temperature of the second window 73, and the adjustment temperature of the third window 78. The optical component having the lowest adjustment temperature may be the EUV light focusing mirror 40.

Specifically, the temperature of hydrogen gas supplied to the chamber 18 is preferably equal to or lower than the temperature of cooling water used by the cooler 250 that cools the EUV light focusing mirror 40. The temperature of hydrogen gas supplied to the chamber 18 more preferably exceeds 0° C. and is equal to or lower than the temperature of cooling water used by the cooler 250 that cools the EUV light focusing mirror 40.

The regulator 206 depressurizes hydrogen gas, the temperature of which is adjusted by the hydrogen temperature adjuster 200. In exemplary hydrogen gas depressurization by the regulator 206, the pressure before the depressurization is 14.0 MPa, and the pressure after the depressurization is 0.4 MPa to 0.7 MPa. The flow rate of hydrogen gas output from the regulator 206 may be 50 liters per minute to 100 liters per minute.

Hydrogen gas depressurized by the regulator 206 is supplied to the first mass flow controller 222. The first mass flow controller 222 controls the flow rate of the hydrogen gas supplied to the first mass flow controller 222.

The hydrogen gas, the flow rate of which is controlled by the first mass flow controller 222 is supplied to the EUV optical sensor unit 60, the second cover 74, and the third cover 79.

Hydrogen gas depressurized by the regulator 206 is supplied to the second mass flow controller 226. The second mass flow controller 226 controls the flow rate of the hydrogen gas supplied to the second mass flow controller 226. The hydrogen gas, the flow rate of which is controlled by the second mass flow controller 226 is supplied to the reflection surface of the EUV light focusing mirror 40 through a hydrogen gas feed unit (not illustrated).

Hydrogen gas depressurized by the regulator 206 is supplied to the third mass flow controller 230. The third mass flow controller 230 controls the flow rate of the hydrogen gas supplied to the third mass flow controller 230. The hydrogen gas, the flow rate of which is controlled by the third mass flow controller 230 is supplied to the first laser reflection mirror 34 and the second laser reflection mirror 36 disposed in the laser beam condensation unit 16.

The gas control device 24 illustrated in FIG. 1 controls operation of the first mass flow controller 222, the second mass flow controller 226, and the third mass flow controller 230 illustrated in FIG. 2 in accordance with the use amount of hydrogen gas at a component to which hydrogen gas is to be supplied.

Hydrogen gas supplied into the chamber 18 flows around the optical component inside the chamber 18 and on the surface of the optical component, and then is collected by the discharge device 62 illustrated in FIG. 1. In addition, stannane gas generated through reaction between hydrogen gas and Sn debris is collected by the discharge device 62 illustrated in FIG. 1. The downward white arrow line illustrated in FIG. 2 represents the flow direction of gas discharged from the chamber 18.

Generation of EUV light may be stopped when the temperature of hydrogen gas supplied into the chamber 18 is detected to be equal to or higher than a predetermined reference value. The temperature of hydrogen gas at the entrance of the chamber 18 may be detected.

4.3 Effect

According to the first embodiment, the hydrogen temperature adjuster 200 is disposed between the gas supply device 61 and the regulator 206 and cools high-pressure hydrogen gas before depressurization. The high-pressure hydrogen gas supplied into the chamber 18 has a high molecule density and thus has a high cooling efficiency. In addition, the hydrogen gas can be cooled through adiabatic expansion of the hydrogen gas. The single hydrogen temperature adjuster 200 can cool the hydrogen gas to be supplied to a plurality of places.

The hydrogen temperature adjuster 200 cools hydrogen gas, the flow rate of which is yet to be controlled. This reduces change of the flow rate of the hydrogen gas due to change of the temperature of the hydrogen gas, which would occur when the hydrogen gas is provided with cooling processing after provided with the flow rate control. The cooling temperature of the hydrogen gas can be set to the hydrogen temperature adjuster 200 in accordance with the cooling temperature of the optical component disposed inside the chamber 18.

The cooled hydrogen gas is supplied to the surface of the optical component disposed inside the chamber 18. The cooled hydrogen gas supplied into the chamber 18 cools the surface of the optical component disposed inside the chamber 18, thereby avoiding increase of the temperature of the optical component.

When increase of the temperature of the optical component is avoided, tin generation from stannane gas can be avoided. Since gas inside the chamber 18 is collected by the discharge device 62, stannane gas is discharged in the state of gas to the outside of the chamber 18 by the discharge device 62. This reduces tin contamination of the optical component such as adhesion of tin generated from stannane gas to the optical component.

Hydrogen gas collected by the discharge device 62 is not reused. Hydrogen gas having an impurity content rate managed to be low is supplied from the gas supply device 61 into the chamber 18. Exemplary impurities include tin and tin compound. Exemplary hydrogen gas having a low impurity content rate includes hydrogen gas, the content rate of tin and tin compound of which is equal to or lower than 100 ppm.

### 5. Second Embodiment

5.1 Configuration

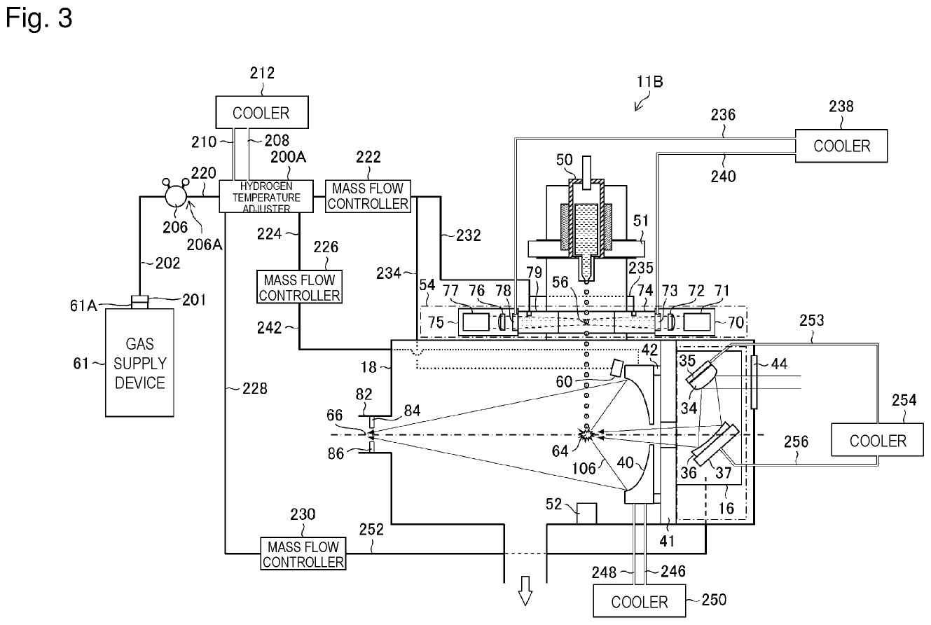

FIG. 3 is a diagram schematically illustrating the configuration of an EUV light generation apparatus according to a second embodiment. In this EUV light generation apparatus 11B illustrated in FIG. 3, a hydrogen temperature adjuster 200A is disposed on a gas pipe between the regulator 206 and the first mass flow controller 222, a gas pipe between the regulator 206 and the second mass flow controller 226, and a gas pipe between the regulator 206 and the third mass flow controller 230.

In other words, the hydrogen temperature adjuster 200A is an exemplary temperature adjustment unit connected with a hydrogen gas supply path downstream of a regulator and upstream of a mass flow controller. The gas pipe 220 is an exemplary hydrogen gas supply path downstream of a regulator and upstream of a mass flow controller.

The EUV light generation apparatus 11B is an exemplary extreme ultraviolet light generation device. The gas pipe 202 is an exemplary component of the hydrogen gas supply path. The combination of the hydrogen temperature adjuster 200A and the cooler 212 is an exemplary temperature adjustment unit.

The gas supply device 61 may include the regulator 206. When the gas supply device 61 includes the regulator 206, a joint provided at an end of the gas pipe 220 is coupled with an output unit 206A of the regulator 206. The joint provided at the end of the gas pipe 220 is not illustrated.

When the gas supply device 61 includes the regulator 206, the output unit 206A of the regulator 206 corresponds to a hydrogen-gas output unit of a hydrogen gas supply device. When the gas supply device 61 includes the regulator 206, flow paths downstream of the output unit 206A of the regulator 206, such as the gas pipe 220, the gas pipe 224, the gas pipe 228, the gas pipe 232, and the gas pipe 234 are exemplary components of the hydrogen gas supply path.

In the EUV light generation apparatus 11B, components on the chamber 18 side of the hydrogen temperature adjuster 200A, which are downstream of the hydrogen temperature adjuster 200A on the circulation path of hydrogen gas, are provided with dew condensation prevention. The dew condensation prevention may be same as that in the first embodiment.

5.2 Operation

Hydrogen gas fed out from the gas supply device 61 is depressurized into a range from 0.4 MPa to 0.7 MPa by the regulator 206. The hydrogen gas depressurized by the regulator 206 is supplied to the hydrogen temperature adjuster 200A. The hydrogen temperature adjuster 200A adjusts, by using the cooler 212, the temperature of the depressurized hydrogen gas supplied to the hydrogen temperature adjuster 200A. Conditions of the hydrogen gas temperature adjustment by the hydrogen temperature adjuster 200A may be same as conditions of the temperature adjustment by the hydrogen temperature adjuster 200 described in the first embodiment.

The hydrogen gas, the temperature of which is adjusted by the hydrogen temperature adjuster 200A is supplied to the first mass flow controller 222. The first mass flow controller 222 controls the flow rate of the hydrogen gas supplied to the first mass flow controller 222.

The hydrogen gas, the flow rate of which is controlled by the first mass flow controller 222 is supplied to the EUV optical sensor unit 60, the second cover 74, and the third cover 79.

The hydrogen gas, the temperature of which is adjusted by the hydrogen temperature adjuster 200A is supplied to the second mass flow controller 226. The second mass flow controller 226 controls the flow rate of the hydrogen gas supplied to the second mass flow controller 226.

The hydrogen gas, the flow rate of which is controlled by the second mass flow controller 226 is supplied to the reflection surface of the EUV light focusing mirror 40 through the hydrogen gas feed unit (not illustrated).

The hydrogen gas, the temperature of which is adjusted by the hydrogen temperature adjuster 200A is supplied to the third mass flow controller 230. The third mass flow controller 230 controls the flow rate of the hydrogen gas supplied to the third mass flow controller 230.

The hydrogen gas, the flow rate of which is controlled by the third mass flow controller 230 is supplied to the surface of the first laser reflection mirror 34 and the surface of the second laser reflection mirror 36 disposed in the laser beam condensation unit 16.

5.3 Effect

According to the second embodiment, the hydrogen temperature adjuster 200A is disposed between the regulator 206 and each mass flow controller. The hydrogen temperature adjuster 200A cools hydrogen gas depressurized into the range from 0.4 MPa to 0.7 MPa by the regulator 206. The hydrogen gas depressurized into the range from 0.4 MPa to 0.7 MPa has a pressure higher than the pressure of hydrogen gas at a supply inlet of the chamber 18 and has a high molecule density, and thus temperature adjustment can be achieved at temperature adjustment efficiency in accordance with the high molecule density.

The hydrogen temperature adjuster 200 cools hydrogen gas, the flow rate of which is yet to be controlled. This reduces change of the flow rate of the hydrogen gas due to change of the temperature of the hydrogen gas, which would occur when the hydrogen gas is provided with cooling processing after provided with the flow rate control.

The adjustment temperature of hydrogen gas can be set to the hydrogen temperature adjuster 200 in accordance with the adjustment temperature of the optical component disposed inside the chamber 18. The single hydrogen temperature adjuster 200 can adjust the temperature of hydrogen gas supplied to a plurality of places.

Increase of the temperature of the optical component inside the chamber 18 can be avoided through cooling at high efficiency, thereby avoiding tin generation from stannane gas. Since gas inside the chamber 18 is collected by the discharge device 62, stannane gas is discharged in the state of gas to the outside of the chamber 18 by the discharge device 62. This reduces tin contamination of the optical component such as adhesion of tin generated from stannane gas to the optical component.

Accordingly, dew condensation prevention becomes unnecessary between the gas supply device 61 and the regulator 206. A region provided with dew condensation prevention is reduced as compared to the configuration in which the hydrogen temperature adjuster 200 is disposed between the gas supply device 61 and the regulator 206, which decreases the difficulty of dew condensation prevention. In addition, the accuracy of the temperature of hydrogen gas in a region in which the hydrogen gas is used is increased as compared to the configuration in which the hydrogen temperature adjuster 200 is disposed between the gas supply device 61 and the regulator 206.

### 6. Third Embodiment

6.1 Configuration

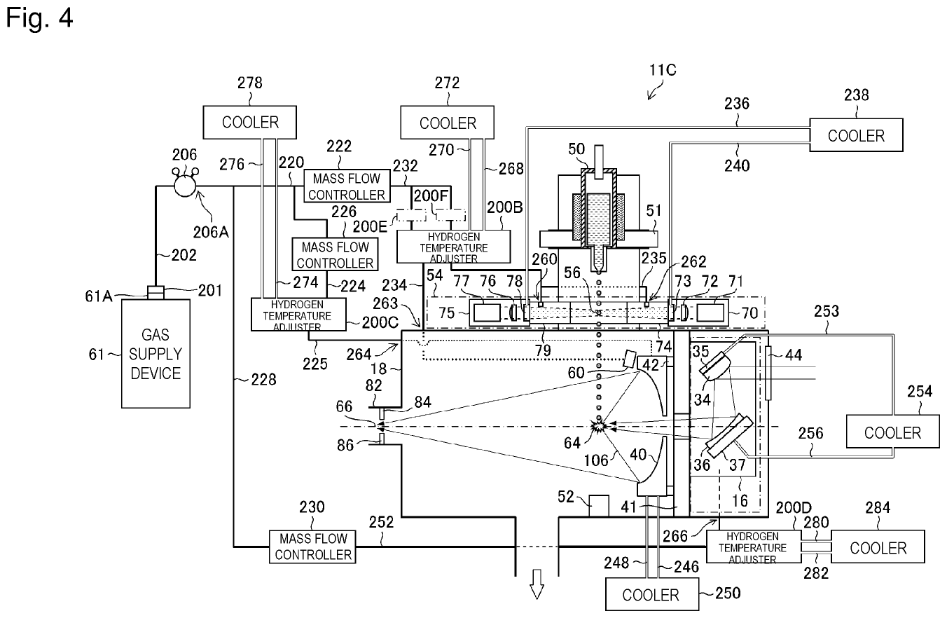

FIG. 4 is a diagram schematically illustrating the configuration of an EUV light generation apparatus according to a third embodiment. In this EUV light generation apparatus 11C illustrated in FIG. 4, a hydrogen temperature adjuster is disposed between the chamber 18 and each of the first mass flow controller 222, the second mass flow controller 226, and the third mass flow controller 230. The EUV light generation apparatus 11C is an exemplary extreme ultraviolet light generation device.

A first hydrogen temperature adjuster 200B is disposed on the gas pipe 232 between the first mass flow controller 222 and a first entrance 260. The first hydrogen temperature adjuster 200B is also disposed on the gas pipe 235 between the first mass flow controller 222 and a second entrance 262. The first hydrogen temperature adjuster 200B is also disposed on the gas pipe 234 between the first mass flow controller 222 and a third entrance 263.

A second hydrogen temperature adjuster 200C is disposed on a gas pipe 225 between the second mass flow controller 226 and a fourth entrance 264. A third hydrogen temperature adjuster 200D is disposed on the gas pipe 252 between the third mass flow controller 230 and a fifth entrance 266.

The first hydrogen temperature adjuster 200B, the second hydrogen temperature adjuster 200C, and the third hydrogen temperature adjuster 200D are each an exemplary temperature adjustment unit connected with the hydrogen gas supply path downstream of a mass flow controller. The gas pipe 232, the gas pipe 224, the gas pipe 225, the gas pipe 234, the gas pipe 235, and the gas pipe 252 are each an exemplary hydrogen gas supply path downstream of a mass flow controller.

The first hydrogen temperature adjuster 200B is connected with a cooler 272 through a cooling water pipe 268 and a cooling water pipe 270. The second hydrogen temperature adjuster 200C is connected with a cooler 278 through a cooling water pipe 274 and a cooling water pipe 276. The third hydrogen temperature adjuster 200D is connected with a cooler 284 through a cooling water pipe 280 and a cooling water pipe 282.

The combination of the first hydrogen temperature adjuster 200B and the cooler 272 is an exemplary temperature adjustment unit. The combination of the second hydrogen temperature adjuster 200C and the cooler 278 is an exemplary temperature adjustment unit. The combination of the third hydrogen temperature adjuster 200D and the cooler 284 is an exemplary temperature adjustment unit.

In the EUV light generation apparatus 11C, components on the chamber 18 side of the first hydrogen temperature adjuster 200B, which are downstream of the first hydrogen temperature adjuster 200B on the circulation path of hydrogen gas, are provided with dew condensation prevention. In the EUV light generation apparatus 11C, components on the chamber 18 side of the second hydrogen temperature adjuster 200C, which are downstream of the second hydrogen temperature adjuster 200C, are provided with dew condensation prevention. In the EUV light generation apparatus 11C, components on the chamber 18 side of the third hydrogen temperature adjuster 200D, which are downstream of the third hydrogen temperature adjuster 200D, are provided with dew condensation prevention. The dew condensation prevention may be same as that in each of the first and second embodiments.

6.2 Operation

The gas supply device 61 feeds out hydrogen gas. The hydrogen gas fed out from the gas supply device 61 is supplied to the regulator 206. The regulator 206 depressurizes the hydrogen gas supplied to the regulator 206 into the range from 0.4 MPa to 0.7 MPa. The hydrogen gas depressurized by the regulator 206 is supplied to the first mass flow controller 222, the second mass flow controller 226, and the third mass flow controller 230.

The first mass flow controller 222 controls the flow rate of the hydrogen gas supplied to the first mass flow controller 222. The hydrogen gas, the flow rate of which is controlled by the first mass flow controller 222 is supplied to the first hydrogen temperature adjuster 200B.

The first hydrogen temperature adjuster 200B adjusts, by using the cooler 272, the temperature of the hydrogen gas supplied to the first hydrogen temperature adjuster 200B. The hydrogen gas, the temperature of which is adjusted by the first hydrogen temperature adjuster 200B is supplied to the EUV optical sensor unit 60, the second cover 74, and the third cover 79.

The second mass flow controller 226 controls the flow rate of the hydrogen gas supplied to the second mass flow controller 226. Hydrogen gas, the flow rate of which is controlled by the second mass flow controller 226 is supplied to the second hydrogen temperature adjuster 200C.

The second hydrogen temperature adjuster 200C adjusts, by using the cooler 278, the temperature of the hydrogen gas supplied to the second hydrogen temperature adjuster 200C. The hydrogen gas, the temperature of which is adjusted by the second hydrogen temperature adjuster 200C is supplied to the surface of the EUV light focusing mirror 40 through a gas supply unit (not illustrated).

The third mass flow controller 230 controls the flow rate of the hydrogen gas supplied to the third mass flow controller 230. The hydrogen gas, the flow rate of which is controlled by the third mass flow controller 230 is supplied to the third hydrogen temperature adjuster 200D.

The third hydrogen temperature adjuster 200D adjusts, by using the cooler 284, the temperature of the hydrogen gas supplied to the third hydrogen temperature adjuster 200D. The hydrogen gas, the temperature of which is adjusted by the third hydrogen temperature adjuster 200D is supplied to the surface of the first laser reflection mirror 34 and the surface of the second laser reflection mirror 36 disposed in the laser beam condensation unit 16.

6.3 Effect

According to the third embodiment, the hydrogen gas supplied to the first hydrogen temperature adjuster 200B, the second hydrogen temperature adjuster 200C, and the third hydrogen temperature adjuster 200D has a low pressure of 100 Pa approximately and thus has a low density and low cooling efficiency, but can cool the optical component inside the chamber 18. Increase of the temperature of the optical component inside the chamber 18 can be avoided by cooling the optical component inside the chamber 18.

The hydrogen gas supplied into the chamber 18 is collected by the discharge device 62. Increase of the temperature of the optical component inside the chamber 18 can be avoided by cooling the optical component inside the chamber 18. Tin generation from stannane gas can be avoided by avoiding increase of the temperature of the optical component.

Tin generation from stannane gas can be avoided by avoiding increase of the temperature of the optical component. Since gas inside the chamber 18 is collected by the discharge device 62, stannane gas is discharged in the state of gas to the outside of the chamber 18 by the discharge device 62. This reduces tin contamination of the optical component such as adhesion of tin generated from stannane gas to the optical component.

The first hydrogen temperature adjuster 200B, the second hydrogen temperature adjuster 200C, and the third hydrogen temperature adjuster 200D are each disposed on a gas pipe line on the chamber 18 side of a mass flow controller. The temperature of hydrogen gas, the flow rate of which is controlled by each of the first mass flow controller 222, the second mass flow controller 226, and the third mass flow controller 230 can be adjusted individually for each temperature adjustment target. In addition, the increased number of hydrogen temperature adjusters allow individual cooling of each cooling target.

Moreover, a region provided with dew condensation prevention is reduced as compared to that in each of the first and second embodiments, which decreases the difficulty of dew condensation prevention as compared to that in each of the first and second embodiments. The accuracy of the temperature of hydrogen gas in a region in which the hydrogen gas is used is increased as compared to that in each of the first and second embodiments. Since temperature adjustment is performed downstream of each mass flow controller, the flow rate stability degrades as compared to that in each of the first and second embodiments, but can be maintained at a level with no problem in practical use.

Although the present disclosure exemplarily describes the configuration in which one hydrogen temperature adjuster is provided for each mass flow controller, a plurality of hydrogen temperature adjusters may be provided for each mass flow controller. For example, hydrogen temperature adjusters may be provided between the first mass flow controller 222 and the first entrance 260, between the first mass flow controller 222 and the second entrance 262, and between the first mass flow controller 222 and the third entrance 263. In other words, the first hydrogen temperature adjuster 200B may be replaced with a fourth hydrogen temperature adjuster 200E connected with the gas pipe 234, and may be replaced with a fifth hydrogen temperature adjuster 200F connected with the gas pipe 232. The gas pipe 235 may be connected with a hydrogen temperature adjuster (not illustrated). The fourth hydrogen temperature adjuster 200E, the fifth hydrogen temperature adjuster 200F, and the hydrogen temperature adjuster (not illustrated) are each connected with a cooler (not illustrated) through a cooling water pipe (not illustrated).

### 7. Fourth Embodiment

7.1 Configuration

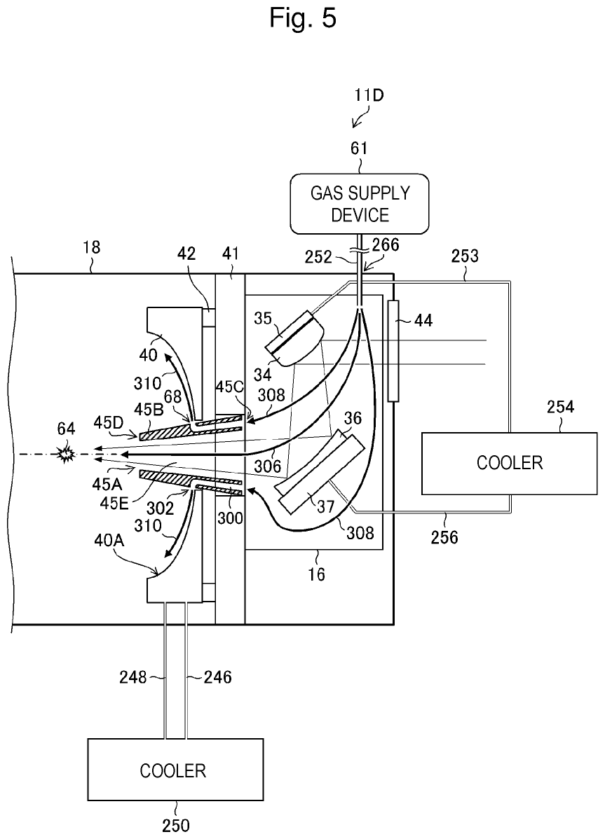

FIG. 5 is a partially enlarged view of an EUV light generation apparatus according to a fourth embodiment. This EUV light generation apparatus 11D according to the fourth embodiment includes a first cover 45B having a function to supply hydrogen gas along a reflection surface 40A of the EUV light focusing mirror 40. The first cover 45B is provided to the through-hole 68 of the EUV light focusing mirror 40. The first cover 45B is an exemplary hydrogen gas flow path structural member.

The first cover 45B illustrated in FIG. 5 includes a gas flow path 300 and a gas blow hole 302. The gas flow path 300 is formed along the bus bar direction of the first cover 45B from a base end 45C of the first cover 45B. The gas flow path 300 may be formed entirely or partially in the circumferential direction of the first cover 45B.

The gas blow hole 302 is formed at the outer peripheral surface of the first cover 45B. A plurality of gas blow holes 302 may be formed on the outer peripheral surface of the first cover 45B in the circumferential direction of the first cover 45B. The gas blow hole 302 may be formed as a groove in the circumferential direction of the first cover 45B.

An edge of the gas flow path 300 on a side closer to a leading end 45D of the first cover 45B is connected with the gas blow hole 302. The gas blow hole 302 is disposed at a position where at least part of the gas blow hole 302 is exposed on the leading end 45D side of the first cover 45B from the reflection surface of the EUV light focusing mirror 40.

7.2 Operation

The temperature of hydrogen gas output from the gas supply device 61 is adjusted to 16° C. or lower by a hydrogen temperature adjuster (not illustrated). The hydrogen gas, the temperature of which is adjusted to 16° C. or lower is supplied to the laser beam condensation unit 16. The hydrogen gas supplied to the laser beam condensation unit 16 is supplied to the first window 44, the surface of the first laser reflection mirror 34, and the surface of the second laser reflection mirror 36. The first laser reflection mirror 34 and the second laser reflection mirror 36 are exemplary reflection mirrors.

The hydrogen gas supplied to the laser beam condensation unit 16 is supplied from the base end 45C of the first cover 45B to the inside of a hollow part 45E of the first cover 45B. The arrow line denoted by reference sign 306 represents the flow of the hydrogen gas passing through the hollow part 45E of the first cover 45B.

The hydrogen gas supplied to the laser beam condensation unit 16 is supplied from the base end 45C of the first cover 45B to the gas flow path 300. The arrow line denoted by reference sign 308 represents the flow of the hydrogen gas supplied from the base end 45C of the first cover 45B to the gas flow path 300.

The hydrogen gas supplied to the gas flow path 300 is supplied to the reflection surface of the EUV light focusing mirror 40 through the gas blow hole 302. The arrow line denoted by reference sign 310 represents the flow of the hydrogen gas supplied to the reflection surface of the EUV light focusing mirror 40 through the gas blow hole 302. The EUV light focusing mirror 40 is an exemplary focusing mirror.

7.3 Effect

According to the fourth embodiment, the hydrogen gas having a temperature equal to or lower than 16° C. and supplied to the laser beam condensation unit 16 is supplied to the reflection surface of the EUV light focusing mirror 40 through the gas flow path 300 and the gas blow hole 302 of the first cover 45B. The hydrogen gas supplied to the reflection surface of the EUV light focusing mirror 40 flows along the reflection surface of the EUV light focusing mirror 40.

When the reflection surface of the EUV light focusing mirror 40 is irradiated with laser, plasma, EUV light, and the like, temperature increase can occur to the reflection surface of the EUV light focusing mirror 40. Although the inside of the EUV light focusing mirror 40 is cooled by the cooler 250, the cooling of the inside of the EUV light focusing mirror 40 is achieved through heat conduction, and thus it is difficult to effectively cool the reflection surface of the EUV light focusing mirror 40.

The reflection surface of the EUV light focusing mirror 40 can be directly cooled by supplying hydrogen gas to the reflection surface of the EUV light focusing mirror 40, and thus can be effectively cooled. Increase of the temperature of the reflection surface of the EUV light focusing mirror 40 can be avoided by effectively cooling the reflection surface of the EUV light focusing mirror 40.

Tin generation from stannane gas can be avoided by avoiding increase of the temperature of the optical component. Since gas inside the chamber 18 is collected by the discharge device 62, stannane gas is discharged in the state of gas to the outside of the chamber 18 by the discharge device 62. This reduces tin contamination of the optical component such as adhesion of tin generated from stannane gas to the optical component.

Hydrogen gas supplied to the laser beam condensation unit 16 is supplied to the surface of the first window 44, the surface of the first laser reflection mirror 34, and the surface of the second laser reflection mirror 36. The hydrogen gas supplied to the surface of the first window 44, the surface of the first laser reflection mirror 34, and the surface of the second laser reflection mirror 36 flows along the surface of the first laser reflection mirror 34 and the surface of the second laser reflection mirror 36.

Similarly to the surface of the EUV light focusing mirror 40, the surfaces of the first window 44, the first laser reflection mirror 34, and the second laser reflection mirror 36 can be directly cooled through the hydrogen gas supply, and thus can be effectively cooled.

### 8. Fifth Embodiment

8.1 Configuration

FIG. 6 is a partially enlarged view of an EUV light generation apparatus according to a fifth embodiment. This EUV light generation apparatus 11E according to the fifth embodiment includes a hydrogen gas feed unit 320.

The hydrogen gas feed unit 320 includes a gas entrance 330, a gas flow path 332, a gas exit 334, and a gas exit 344. The gas entrance 330 is connected with the fourth entrance 264. The gas entrance 330 is connected with the gas flow path 332. The gas flow path 332 illustrated in FIG. 6 is an annular pipe along the outer peripheral surface of the reflection surface of the EUV light focusing mirror 40. The gas exit 334 and the gas exit 344 are formed on the gas flow path 332.

In the hydrogen gas feed unit 320 illustrated in FIG. 6, the gas exit 334 and the gas exit 344 are formed at positions opposite to each other across the center of the reflection surface of the EUV light focusing mirror 40. A plurality of gas exits included in the hydrogen gas feed unit 320 are not limited to the example illustrated in FIG. 6. The gas flow path 332 may include three or more gas exits. The three or more gas exits are preferably disposed at equal intervals. Each gas exit included in the gas flow path 332 may be a slit along the outer peripheral surface of the reflection surface of the EUV light focusing mirror 40.

8.2 Operation

The temperature of hydrogen gas output from the gas supply device 61 is adjusted to 16° C. or lower, in particular, to the cooling temperature of the EUV light focusing mirror 40 or lower by a hydrogen temperature adjuster (not illustrated). The hydrogen gas, the temperature of which is adjusted is supplied to the hydrogen gas feed unit 320 through the fourth entrance 264. The hydrogen gas having flowed into the hydrogen gas feed unit 320 through the fourth entrance 264 is supplied to the reflection surface of the EUV light focusing mirror 40 through the gas flow path 332, the gas exit 334, and the gas exit 344.

The hydrogen gas having the adjusted temperature and supplied to the reflection surface of the EUV light focusing mirror 40 through the gas exit 334 and the gas exit 344 flows along the reflection surface of the EUV light focusing mirror 40. The hydrogen gas feed unit 320 is an exemplary hydrogen gas flow path structural member.

8.3 Effect

According to the fifth embodiment, the hydrogen gas feed unit 320 includes the gas exit 334 and the gas exit 344 formed around the reflection surface of the EUV light focusing mirror 40. The hydrogen gas feed unit 320 supplies hydrogen gas, the temperature of which is adjusted to the reflection surface of the EUV light focusing mirror 40. The hydrogen gas supplied to the reflection surface of the EUV light focusing mirror 40 flows along the reflection surface of the EUV light focusing mirror 40. Accordingly, the reflection surface of the EUV light focusing mirror 40 can be directly cooled, and thus can be effectively cooled. Increase of the temperature of the reflection surface of the EUV light focusing mirror 40 can be avoided by effectively cooling the reflection surface of the EUV light focusing mirror 40.

Tin generation from stannane gas can be avoided by avoiding increase of the temperature of the optical component. Since gas inside the chamber 18 is collected by the discharge device 62, stannane gas is discharged in the state of gas to the outside of the chamber 18 by the discharge device 62. This reduces tin contamination of the optical component such as adhesion of tin generated from stannane gas to the optical component.

### 9. Sixth Embodiment

9.1 Configuration

FIG. 7 is a cross-sectional view illustrating the configuration of an EUV optical sensor unit in an EUV light generation apparatus according to a sixth embodiment. This EUV optical sensor unit 60A illustrated in FIG. 7 is disposed inside the chamber 18. The EUV optical sensor unit 60A is fixed to a wall 18A of the chamber 18.

The EUV optical sensor unit 60A includes an EUV light reflection mirror 400, a wavelength filter 402, and an EUV sensor 404.

The EUV light reflection mirror 400 is made of a multi-layer reflective film that selectively reflects light including EUV light in light radiated from plasma. The EUV light reflection mirror 400 may be made of, for example, a Mo/Si multi-layered film obtained by alternately stacking molybdenum (Mo) and silicon (Si).

The wavelength filter 402 selectively transmits light having an EUV light wavelength in the light reflected by the EUV light reflection mirror 400. The wavelength of EUV light transmitting through the wavelength filter 402 is, for example, 13.5 nm. For example, the wavelength filter 402 is a metal filter having a film thickness of 300 nm to 600 nm, and may be a metal thin film filter made of zirconium (Zr). The wavelength filter 402 is disposed over the light-receiving surface of the EUV sensor 404. EUV light having a desired wavelength can be made incident on the EUV sensor 404 by combining the reflection characteristic of the EUV light reflection mirror 400 and the transmission characteristic of the wavelength filter 402.

The EUV sensor 404 is a sensor such as a photodiode configured to detect the energy of incident light. The EUV sensor 404 outputs an electric signal in accordance with the amount of received light. The signal output from the EUV sensor 404 is transferred to the EUV light generation control device 20.

The EUV optical sensor unit 60A includes a hollow case 410 in which the EUV light reflection mirror 400, the wavelength filter 402, and the EUV sensor 404 are disposed. The case 410 includes an optical component housing unit 412, a cylindrical unit 414, and a gas feed unit 416.

The optical component housing unit 412 is a space in which the EUV light reflection mirror 400, the wavelength filter 402, and the EUV sensor 404 are disposed. The EUV light reflection mirror 400 is held by a mirror holder (not illustrated). The EUV sensor 404 is attached to part of the wall surface of the case 410, which defines the optical component housing unit 412. The EUV light reflection mirror 400 is an exemplary reflection mirror. The EUV sensor 404 is an exemplary sensor. The wavelength filter 402 is held by a filter holder 403. The wavelength filter 402 is disposed on the front surface of the EUV sensor 404.

The cylindrical unit 414 includes an opening 415 as a light incident port of plasma light including EUV light. The opening 415 illustrated in FIG. 7 corresponds to the opening 135 illustrated in FIG. 1. The cylindrical unit 414 is provided with a plate member 422 on which an aperture 420 is formed and a dimmer mesh filter 424. The mesh filter 424 is an exemplary dimmer filter.

Plasma light incident through the opening 415 passes through the aperture 420 and the mesh filter 424 and is incident on the EUV light reflection mirror 400. The arrow line denoted by reference sign 419 represents the plasma light.

The case 410 is inserted into and engaged with a socket 440. The socket 440 is formed so that a gap 442 is formed between the outer wall of the case 410 and the inner wall of the socket 440 when the socket 440 is engaged with the case 410. The gap 442 may be formed entirely around the inner wall of the socket 440.

The gap 442 functions as a gas path. The socket 440 includes a gas pipe connection unit 444. The gas pipe connection unit 444 is connected with a gas pipe 446. The gas pipe 446 illustrated in FIG. 7 corresponds to part of the gas pipe 234 illustrated in FIG. 2 inside the chamber 18.

A gas entrance 417 is formed at part of the outer wall of the case 410, which faces to the gap 442. The gas feed unit 416 connecting the gas entrance 417 and a gas exit 418 is formed so that hydrogen gas introduced into the case 410 blows toward the EUV light reflection mirror 400. The gas feed unit 416 is an exemplary hydrogen gas flow path structural member.

The case 410 is fixed to the wall 18A of the chamber 18 through a flange part 450. The flange part 450 of the case 410 is disposed inside the chamber 18 and fixed to the wall 18A of the chamber 18 through a gasket 452.

9.2 Operation

Hydrogen gas fed out from the gas supply device 61 illustrated in FIG. 2 and having a temperature adjusted to 16° C. or lower is supplied to the gap 442 through the gas pipe 234, and the gas pipe 446 and the gas pipe connection unit 444 illustrated in FIG. 7. The hydrogen gas supplied to the gap 442 is supplied to the optical component housing unit 412 through the gas feed unit 416. The arrow line denoted by reference sign 460 and the arrow line denoted by reference sign 462 represent the flow of hydrogen gas.

The hydrogen gas supplied to the optical component housing unit 412 flows along the surface of the EUV light reflection mirror 400, the surface of the wavelength filter 402, and the surface of the EUV sensor 404 disposed in the optical component housing unit 412. The hydrogen gas supplied to the optical component housing unit 412 also flows into the cylindrical unit 414. The hydrogen gas having flowed into the cylindrical unit 414 flows along the surface of the mesh filter 424. The arrow line denoted by reference sign 464 represents the flow of hydrogen gas from the gas feed unit 416 toward the surface of the EUV sensor 404. The arrow line denoted by reference sign 465 represents the flow of hydrogen gas toward the mesh filter 424. The arrow line denoted by reference sign 466 represents the flow of hydrogen gas in the cylindrical unit 414.

9.3 Effect

According to the sixth embodiment, hydrogen gas, the temperature of which is adjusted to 16° C. or lower is supplied to the surfaces of the EUV light reflection mirror 400, the wavelength filter 402, the EUV sensor 404, and the mesh filter 424 included in the EUV optical sensor unit 60A.

In the EUV optical sensor unit 60A, the surface of the EUV light reflection mirror 400 and the surface of the EUV sensor 404 can be cooled at high cooling efficiency by supplying hydrogen gas, the temperature of which is adjusted to 16° C. or lower to the surface of the EUV light reflection mirror 400 and the surface of the EUV sensor 404. Increase of the temperatures of the surface of the EUV light reflection mirror 400 and the surface of the EUV sensor 404 can be avoided by cooling the surface of the EUV light reflection mirror 400 and the surface of the EUV sensor 404 at high cooling efficiency.

It is difficult to directly cool thin-film optical components such as the wavelength filter 402 and the mesh filter 424 with water due to their structures. In the EUV optical sensor unit 60A, the wavelength filter 402 and the mesh filter 424 can be directly cooled by supplying hydrogen gas, the temperature of which is adjusted to 16° C. or lower to the surfaces of the wavelength filter 402 and the mesh filter 424.

In addition, the wavelength filter 402 and the mesh filter 424 can be cooled at high cooling efficiency. Increase of the temperatures of the wavelength filter 402 and the mesh filter 424 can be avoided by cooling the wavelength filter 402 and the mesh filter 424 at high cooling efficiency.

Tin generation from stannane gas can be avoided by avoiding increase of the temperatures of the wavelength filter 402 and the mesh filter 424. Gas inside the EUV optical sensor unit 60A is discharged through the cylindrical unit 414 and the opening 415, and thus stannane gas is discharged in the state of gas from the EUV optical sensor unit 60A. This reduces tin contamination of the optical component such as adhesion of tin generated from stannane gas to the surface of the EUV light reflection mirror 400, the surface of the EUV sensor 404, the wavelength filter 402, or the mesh filter 424.

### 10. Seventh Embodiment

10.1 Configuration

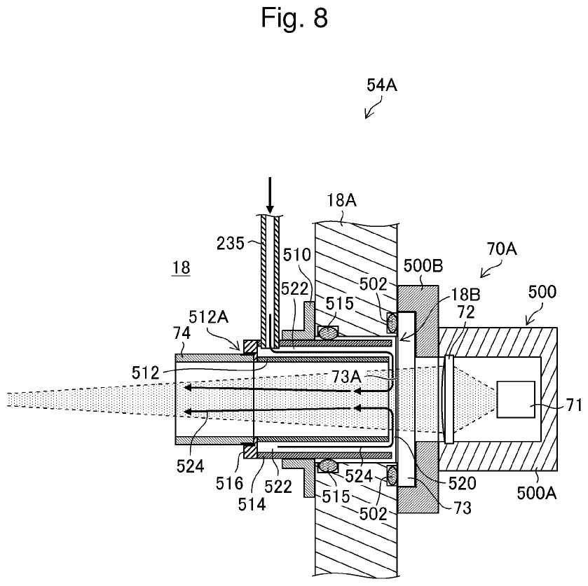

FIG. 8 is a cross-sectional view illustrating the configuration of a droplet detection device of an EUV light generation apparatus according to a seventh embodiment. In the present disclosure, a light source unit 70A of this droplet detection device 54A will be described below.

The light source unit 70A includes a holder 500, the light source 71, and the illumination optical system 72. The holder 500 includes a light source holder 500A and a window holder 500B. The light source 71 and the illumination optical system 72 are disposed at the light source holder 500A.

The wall 18A of the chamber 18 is provided with a through-hole 18B. The second window 73 is attached to the wall 18A of the chamber 18 so that the through-hole 18B is blocked by the window holder 500B. An O ring 502 is disposed between the second window 73 and the wall 18A of the chamber 18.

The light source unit 70A includes a flange 510, a first pipe 512, and a second pipe 514. The outer diameter of the first pipe 512 is smaller than the inner diameter of the second pipe 514. The first pipe 512 is inserted into the second pipe 514 so that the central axis of the first pipe 512 is aligned with the central axis of the second pipe 514.

The alignment in the present specification includes effective alignment that is not complete alignment in reality but with which effects same as those of the complete alignment can be obtained.

At least part of the first pipe 512 is disposed in the through-hole 18B. The first pipe 512 is disposed with a gap formed between the base end of the first pipe 512 and the second window 73. The size of the gap may be substantially uniform.

A plurality of slits having the same size may be formed at the base end of the first pipe 512 at equal intervals in the circumferential direction of the first pipe 512. In this case, parts other than the slits may contact the second window 73 but may have a slight gap therebetween.

Alternatively, a plurality of holes having the same size may be formed near an end part of the first pipe 512 at equal intervals in the circumferential direction. In this case, the end part of the first pipe 512 may contact the second window 73 but may have a slight gap therebetween.

A lid unit 516 is attached to a leading end 512A of the first pipe 512 to block a space 522 between the first pipe 512 and the second pipe 514. The lid unit 516 may be separated from the first pipe 512. The lid unit 516 may be the leading end 512A of the first pipe 512.

The second cover 74 is attached to the lid unit 516. The third cover 79 is attached to a lid unit attached to a leading end of a first pipe of the light receiving unit 75 (not illustrated). The second cover 74 may include the first pipe 512, the second pipe 514, and the lid unit 516. This is same for the third cover 79.

At least part of the second pipe 514 is disposed in the through-hole 18B. An O ring 515 is disposed between the second pipe 514 and the chamber 18. An O ring groove of the O ring 515 may be fabricated on the second pipe 514. The second pipe 514 is attached to the chamber 18 through the flange 510.

The gas pipe 235 is connected with the second pipe 514. The gap between the base end of the first pipe 512 and the second window 73 may define an ejection part 520. A space defined between the first pipe 512 and the second pipe 514 serves as a hydrogen gas flow path. The ejection part 520 may be a gap, a plurality of slits, or a plurality of holes. The size of the gap between the first pipe 512 and the second window 73 may be 0.2 mm to 0.5 mm.

The gas pipe 235, the space 522 between the first pipe 512 and the second pipe 514, and the ejection part 520 define a hydrogen gas flow path connecting the gas pipe 235, the space 522 between the first pipe 512 and the second pipe 514, and the ejection part 520.

The length of the first pipe 512 may be the distance between the ejection part 520 and the leading end 512A of the first pipe 512. The distance between the ejection part 520 and the leading end 512A of the first pipe 512 may exceed the distance between the inner surface of the chamber 18 and the leading end 512A of the first pipe 512.

A capping film 73A is formed on the surface of the second window 73. The capping film 73A may be made of an oxide or a nitride. Specific examples of the material of the capping film 73A include alumina (Al₂O₃), zirconia (ZrO₂), titania (TiO₂), yttria (Y₂O₃), and zirconium nitride (ZrN). The thickness of the capping film may be 10 nm to 100 nm. A capping film similar to that of the second window 73 illustrated in FIG. 8 may be formed on the surface of the optical component inside the chamber 18 such as the third window 78 illustrated in FIG. 2.

The surface of the second window 73 is positioned on the chamber 18 side of the second window 73. The surface of the third window 78 is positioned on the chamber 18 side of the third window 78.

10.2 Operation

Hydrogen gas fed out from the gas supply device 61 illustrated in FIG. 2 and having an adjusted temperature is supplied to the ejection part 520 through the gas pipe 235 and the space 522 between the first pipe 512 and the second pipe 514. The hydrogen gas supplied to the ejection part 520 flows along the surface of the second window 73.

The hydrogen gas supplied to the ejection part 520 flows into the chamber 18 through the first pipe 512. The arrow line denoted by reference sign 524 represents the flow of the hydrogen gas supplied through the gas pipe 235.

A configuration similar to the flow path of hydrogen gas in the light source unit 70A may be employed as the flow path of hydrogen gas in the light receiving unit 75. In the present disclosure, description of the flow path of hydrogen gas in the light receiving unit 75 is omitted.

10.3 Effect

According to the seventh embodiment, hydrogen gas having an adjusted temperature is supplied to the surface of the second window 73 disposed at the light source unit 70A of the droplet detection device 54 and the surface of the third window 78 disposed at the light receiving unit 75.

The insides of the second window 73 and the third window 78 as thick optical components are cooled by the cooler 238 illustrated in FIG. 2. However, the temperatures of the surfaces of the second window 73 and the third window 78 become higher than inside when the surfaces of the second window 73 and the third window 78 are irradiated with laser, plasma, EUV light, and the like. Since the insides of the second window 73 and the third window 78 are cooled through heat conduction, it is difficult to effectively cool the surfaces of the second window 73 and the third window 78.

However, it is possible to directly cool the surfaces of the second window 73 and the third window 78 by causing hydrogen gas to flow along the surfaces of the second window 73 and the third window 78.

Increase of the temperatures of the surfaces of the second window 73 and the third window 78 can be avoided by cooling the surfaces of the second window 73 and the third window 78. Tin generation from stannane gas can be avoided by avoiding increase of the temperatures of the surfaces of the second window 73 and the third window 78.

Gas on the surfaces of the second window 73 and the third window 78 is discharged from a leading end of the second cover 74 and a leading end of the third cover 79 by the flow of hydrogen gas, and thus stannane gas is discharged in the state of gas from the leading end of the second cover 74 and the leading end of the third cover 79. This reduces tin contamination of the optical component such as adhesion of tin generated from stannane gas to the optical component.

The capping film 73A is formed on the surface of the second window 73. The capping film 73A reduces tin adhesion to the surface of the second window 73. Tin adhesion to the surface of the third window 78 is reduced when the capping film is formed on the surface of the third window 78.

In addition, the Peclet number can be increased by increasing the total length of the first pipe 512, and thus the amount of tin reaching the second window 73 can be reduced. The Peclet number can be further increased by attaching the second cover 74 to the leading end of the first pipe 512 to increase the total length of the first pipe 512 and the second cover 74, and thus the amount of tin reaching the second window 73 can be further reduced. The third window 78 can obtain effects similar to those of the second window 73.

The Peclet number Pe representing the degree of diffusion of tin is given by Expression 1 below.

Pe=v×L/Df Expression 1

In the expression, v represents the flow speed (m/s) of gas in a pipe, Df represents the coefficient of diffusion of tin in the gas, and L represents the total length (m) of the pipe. Here, the pipe may be assumed to have a length equal to the sum of the total length of the first pipe 512 and the total length of the second cover 74.

The Peclet number Pe is given Expression 2 below by using a flow rate Q (Pa·m³/s) of the gas passing through the pipe per pressure, a pressure P (Pa) in the pipe, an inner diameter D (m) of the pipe, and a total length (m) of the pipe.

Pe=(Q/P)×{4/(π×D²)}×L/Df Expression 2

### 11. Heat Exchanger

11.1 Configuration

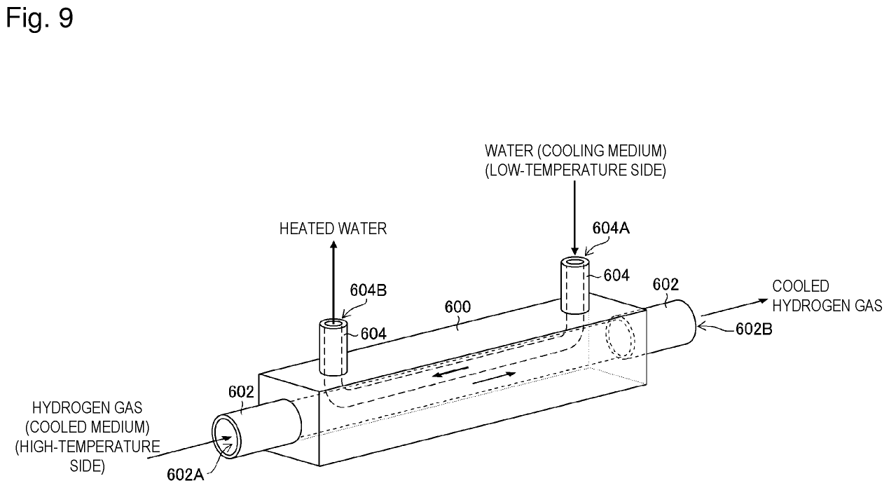

FIG. 9 is a diagram schematically illustrating the configuration of a heat exchanger. The present embodiment describes an example in which hydrogen gas as a cooled medium is cooled by using water as a cooling medium. This heat exchanger 600 illustrated in FIG. 9 includes a first fluid flow path 602 and a second fluid flow path 604.

The first fluid flow path 602 is the flow path of hydrogen gas as a temperature adjustment target. The second fluid flow path 604 is the flow path of water as the cooling medium. The first fluid flow path 602 illustrated in FIG. 9 is disposed inside the second fluid flow path 604. The heat exchanger 600 illustrated in FIG. 9 is merely exemplary, and the heat exchanger of the present disclosure is not limited to the example illustrated in FIG. 9.

The heat exchanger illustrated in FIG. 9 is applicable to the hydrogen temperature adjuster 200 illustrated in FIG. 2, the hydrogen temperature adjuster 200A illustrated in FIG. 3, and the first hydrogen temperature adjuster 200B, the second hydrogen temperature adjuster 200C, and the third hydrogen temperature adjuster 200D illustrated in FIG. 4.

11.2 Operation

Cooling water having a predetermined cooling temperature flows into the second fluid flow path 604 through an entrance 604A. The cooling water passes through the second fluid flow path 604 and is discharged from an exit 604B.

High-temperature hydrogen gas to be cooled flows into the first fluid flow path 602 through an entrance 602A. The hydrogen gas is cooled through heat transfer to the cooling water when passing through the first fluid flow path 602. The hydrogen gas cooled in accordance with the temperature of the cooling water is discharged from an exit 602B of the first fluid flow path 602.

11.3 Effect

Hydrogen gas at room temperature can be adjusted to a temperature equal to or lower than the temperature of the optical component inside the chamber 18 by using the heat exchanger to cool the hydrogen gas.

The heat exchanger 600 illustrated in FIG. 9 is applicable as a heat exchanger of each of the cooler 238, the cooler 250, and the cooler 254 illustrated in FIGS. 2 to 4. When the heat exchanger 600 illustrated in FIG. 9 is applied to the cooler 238, the cooler 250, and the cooler 254 illustrated in FIGS. 2 to 4, the first fluid flow path 602 is the flow path of cooling water, and the second fluid flow path 604 is the flow path of a cooling medium that cools the cooling water. The temperature of the cooling medium may be the temperature of the cooling medium in the second fluid flow path 604.

The above description is intended to provide not restriction but examples. Thus, the skilled person in the art would clearly understood that the embodiments of the present disclosure may be changed without departing from the scope of the claims.

The terms used throughout the specification and the appended claims should be interpreted as “non-limiting”. For example, the term “comprising” or “comprised” should be interpreted as “not limited to what has been described as being comprised”. The term “having” should be interpreted as “not limited to what has been described as having”. It should be understood that the indefinite article “a” in the present specification and the claims means “at least one” or “one or more”.

What is claimed is:

1. An extreme ultraviolet light generation device comprising:
a chamber in which tin is irradiated with a laser beam to generate extreme ultraviolet light;
a hydrogen gas supply path that connects the chamber and a hydrogen-gas output unit of a hydrogen gas supply device as a supply source of hydrogen gas to be supplied into the chamber, receives supply of the hydrogen gas from the hydrogen gas supply device, and supplies, to the chamber, the hydrogen gas supplied from the hydrogen gas supply device;
a temperature adjustment unit connected with the hydrogen gas supply path and configured to adjust the temperature of the hydrogen gas to be equal to or lower than 16° C.; and
a gas discharge unit connected with the chamber and configured to discharge gas including at least hydrogen gas inside the chamber to outside of the chamber.

2. The extreme ultraviolet light generation device according to claim 1, wherein the hydrogen gas supplied from the hydrogen gas supply device does not include the hydrogen gas discharged from the gas discharge unit.

3. The extreme ultraviolet light generation device according to claim 1, wherein the hydrogen gas supply path is connected with the hydrogen-gas output unit of the hydrogen gas supply device of a non-circulation type.

4. The extreme ultraviolet light generation device according to claim 1, wherein the hydrogen gas supplied from the hydrogen gas supply device is hydrogen gas, the content rate of tin and tin compound of which is equal to or lower than 100 ppm.

5. The extreme ultraviolet light generation device according to claim 1, wherein the temperature adjustment unit adjusts the temperature of the hydrogen gas to be equal to or lower than 12° C.

6. The extreme ultraviolet light generation device according to claim 1, wherein the temperature adjustment unit adjusts the temperature of the hydrogen gas to be equal to or higher than 5° C.

7. The extreme ultraviolet light generation device according to claim 1, further comprising:
an optical component disposed in the chamber; and
a hydrogen gas flow path structural member disposed in the chamber and configured to supply the hydrogen gas to a surface of the optical component.

8. The extreme ultraviolet light generation device according to claim 7, further comprising an optical component cooling mechanism configured to cool the optical component by using a cooling medium, wherein the temperature of the hydrogen gas is equal to or lower than the temperature of the cooling medium.

9. The extreme ultraviolet light generation device according to claim 8, wherein the temperature of the hydrogen gas is equal to or lower than the temperature of the cooling medium of the optical component having a lowest cooling temperature.

10. The extreme ultraviolet light generation device according to claim 7, wherein the optical component includes at least one of a sensor, a reflection mirror, a thin film filter, a dimmer filter, and a window.

11. The extreme ultraviolet light generation device according to claim 7, wherein the optical component includes a focusing mirror configured to condense extreme ultraviolet light.

12. The extreme ultraviolet light generation device according to claim 11, wherein the temperature adjustment unit adjusts the temperature of the hydrogen gas to be equal to or lower than the temperature of a cooling medium that cools the focusing mirror.

13. The extreme ultraviolet light generation device according to claim 1, further comprising a regulator configured to adjust the pressure of the hydrogen gas supplied from the hydrogen gas supply device, wherein the temperature adjustment unit is connected with the hydrogen gas supply path upstream of the regulator.

14. The extreme ultraviolet light generation device according to claim 1, further comprising:
a regulator configured to adjust the pressure of the hydrogen gas supplied from the hydrogen gas supply device; and
a mass flow controller configured to control the flow rate of the hydrogen gas supplied from the hydrogen gas supply device,
wherein the temperature adjustment unit is connected with the hydrogen gas supply path downstream of the regulator and upstream of the mass flow controller.

15. The extreme ultraviolet light generation device according to claim 1, further comprising a mass flow controller configured to control the flow rate of the hydrogen gas supplied from the hydrogen gas supply device, wherein the temperature adjustment unit is connected with the hydrogen gas supply path downstream of the mass flow controller.

16. The extreme ultraviolet light generation device according to claim 15, further comprising a plurality of the mass flow controllers.

17. The extreme ultraviolet light generation device according to claim 1, further comprising a mass flow controller configured to control the flow rate of the hydrogen gas supplied from the hydrogen gas supply device, wherein
the temperature adjustment unit is connected with the hydrogen gas supply path downstream of the mass flow controller,
at least one temperature adjustment unit is provided for the mass flow controller, and
at least one optical component is provided for each temperature adjustment unit.

18. The extreme ultraviolet light generation device according to claim 17, wherein a plurality of temperature adjustment units are provided for the mass flow controller.

19. The extreme ultraviolet light generation device according to claim 1, wherein dew condensation prevention is performed for at least one of the hydrogen gas supply path downstream of the temperature adjustment unit and a component through which the hydrogen gas circulates.

20. The extreme ultraviolet light generation device according to claim 1, wherein the hydrogen gas supply path includes a joint connected with the hydrogen-gas output unit of the hydrogen gas supply device.
